(19) United States
(12) Patent Application Publication
(10) Pub. No.: US 2025/0143106 A1
(43) Pub. Date: May 1, 2025

(54) DISPLAY DEVICE

(71) Applicant: Samsung Display Co., LTD., Yongin-si (KR)

(72) Inventors: Keun Woo KIM, Yongin-si (KR); Hyun Eok SHIN, Yongin-si (KR); In Young JUNG, Yongin-si (KR)

(21) Appl. No.: 18/659,933

(22) Filed: May 9, 2024

(30) Foreign Application Priority Data
Oct. 26, 2023 (KR) 10-2023-0144929

(51) Int. Cl. H10K 59/131; H10K 59/121; H10K 77/10; H10K 102/00

(52) U.S. Cl. CPC H10K 59/131; H10K 59/1213; H10K 77/111; H10K 2102/311; H10K 2102/351

(57) ABSTRACT

A display device includes: a substrate; a first display layer on a first surface of the substrate; a second display layer on a second surface of the substrate; a first pixel of the first display layer; and a second pixel of the second display layer, wherein the first pixel and the second pixel comprise different numbers of transistors.

### CROSS-REFERENCE TO RELATED APPLICATION

The present application claims priority to and the benefit of Korean Patent Application No. 10-2023-0144929 filed on Oct. 26, 2023, in the Korean Intellectual Property Office, the entire content of which is incorporated herein by reference.

### BACKGROUND

### 1. Field

Aspects of some embodiments of the present disclosure relate to a display device.

### 2. Description of the Related Art

A head mounted display (HMD) is an image display device that may be worn on a user's head in the form of glasses or helmets to form a focus at a close distance in front of the user's eyes. The head mounted display may implement virtual reality (VR) or augmented reality (AR).

The head mounted display may magnify images displayed on a small display device by using a plurality of lenses, and displays the magnified images. Therefore, the display device applied to the head mounted display may desirably provide high-resolution images, for example, images with a resolution of 3000 PPI (Pixels Per Inch) or higher. To this end, an organic light emitting diode on silicon (OLEDoS), which is a high-resolution small organic light emitting display device, may be used as the display device applied to the head mounted display. The OLEDoS is an image display device in which an organic light emitting diode (OLED) may be formed on a semiconductor wafer substrate on which a complementary metal oxide semiconductor (CMOS) is located.

The above information disclosed in this Background section is only for enhancement of understanding of the background and therefore the information discussed in this Background section does not necessarily constitute prior art.

### SUMMARY

Aspects of some embodiments of the present disclosure relate to a display device, and for example, to a display device with a relatively small thickness and a relatively reduced manufacturing cost.

Aspects of some embodiments of the present disclosure include a display device with a relatively small thickness and a relatively reduced manufacturing cost.

According to some embodiments of the present disclosure, a display device includes: a substrate; a first display layer on a first surface of the substrate; a second display layer on a second surface of the substrate; a first pixel of the first display layer; and a second pixel of the second display layer, wherein the first pixel and the second pixel comprise different numbers of transistors.

According to some embodiments, a second pixel circuit of the second pixel comprises a larger number of transistors than a first pixel circuit of the first pixel.

According to some embodiments, the first pixel circuit comprises five transistors, and the second pixel circuit comprises eight transistors.

According to some embodiments, the first pixel circuit includes: a first transistor including a gate electrode connected to a first node, and connected between a second node and a third node; a second transistor including a gate electrode connected to a first gate line, and connected between a data line and the first node; a third transistor including a gate electrode connected to a third gate line, and connected between a reference voltage line and the first node; a fourth transistor including a gate electrode connected to a second gate line, and connected between a third node and an initialization voltage line; and a fifth transistor including a gate electrode connected to an emission line, and connected between a driving voltage line and the second node.

According to some embodiments, the first to fifth transistors each contain an oxide semiconductor material.

According to some embodiments, the first to fifth transistors are n-type transistors.

According to some embodiments, the second transistor further comprises a counter gate electrode connected to the first gate line, the third transistor further comprises a counter gate electrode connected to the third gate line, and the fourth transistor further comprises a counter gate electrode connected to the second gate line.

According to some embodiments, the first pixel circuit further comprises: a first capacitor connected between the first node and the third node; and a second capacitor connected between the driving voltage line and the third node.

According to some embodiments, the second pixel circuit comprises: a first transistor comprising a gate electrode connected to a third node, and connected between a first node and a second node; a second transistor comprising a gate electrode connected to a first gate line, and connected between a data line and the first node; a third transistor comprising a gate electrode connected to a second gate line, and connected between the third node and the second node; a fourth transistor comprising a gate electrode connected to a third gate line, and connected between the third node and a first initialization voltage line; a fifth transistor comprising a gate electrode connected to an emission line, and connected between a driving voltage line and the first node; a sixth transistor comprising a gate electrode connected to the emission line, and connected between the second node and a fourth node; a seventh transistor comprising a gate electrode connected to a fourth gate line, and connected between the fourth node and a second initialization voltage line; and an eighth transistor comprising a gate electrode connected to the fourth gate line, and connected between a bias voltage line and the first node.

According to some embodiments, the first transistor, the second transistor, the fifth transistor, the sixth transistor, the seventh transistor, and the eighth transistor each contain a silicon-based semiconductor material, and the third transistor and the fourth transistor each contain an oxide semiconductor material.

According to some embodiments, the first transistor, the second transistor, the fifth transistor, the sixth transistor, the seventh transistor, and the eighth transistor are p-type transistors, and the third transistor and the fourth transistor are p-type transistors.

According to some embodiments, the third transistor further comprises a counter gate electrode connected to the second gate line, and the fourth transistor further comprises a counter gate electrode connected to the third gate line.

According to some embodiments, the second pixel circuit further comprises a capacitor connected between the driving voltage line and the third node.

According to some embodiments, the first display layer and the second display layer have different areas.

According to some embodiments, the first display layer has a larger area than that of the second display layer.

According to some embodiments, further comprising a driving circuit on the second surface and connected to the first display layer and the second display layer.

According to some embodiments, the driving circuit is connected to the first display layer through a first pad terminal of the driving circuit, and the driving circuit is connected to the second display layer through a second pad terminal of the driving circuit.

According to some embodiments, the first pad terminal is connected to the first display layer through a first pad on the second surface, and the second pad terminal is connected to the second display layer through a second pad on the second surface.

According to some embodiments, the driving circuit supplies a gate signal, a data signal, and an emission signal to the first display layer through the first pad terminal, and the driving circuit supplies a gate signal, a data signal, and an emission signal to the second display layer through the second pad terminal.

According to some embodiments, the first pixel further comprises a first light emitting element connected to the first pixel circuit, and the second pixel further comprises a second light emitting element connected to the second pixel circuit.

In a display device according to some embodiments of the present disclosure, the thickness and manufacturing cost of the display device can be relatively reduced.

The characteristics of some embodiments of the present disclosure are not limited to the above-described effects and other characteristics which are not described herein will become apparent to those skilled in the art from the following description.

### BRIEF DESCRIPTION OF THE DRAWINGS

The above and other aspects and features of the present disclosure will become more apparent by describing in more detail aspects of some embodiments thereof with reference to the attached drawings, in which:

FIG. 1 is a perspective view of a display device according to some embodiments;

FIG. 2 is an exploded perspective view of the display device of FIG. 1 according to some embodiments;

FIG. 3 is a diagram showing the display device of FIG. 1 in a folded state at a specific angle according to some embodiments;

FIG. 4 is a diagram showing the display device of FIG. 1 in a completely folded state according to some embodiments;

FIG. 5 is an equivalent circuit diagram of the first pixel provided in the first display layer of FIG. 1 according to some embodiments;

FIG. 6 is a cross-sectional view of the first display layer of FIG. 1 according to some embodiments;

FIG. 7 is an equivalent circuit diagram of the second pixel provided in the second display layer of FIG. 1 according to some embodiments;

FIG. 8 is a cross-sectional view of the second display layer of FIG. 1 according to some embodiments;

FIG. 9 is a cross-sectional view illustrating a structure of a display element according to some embodiments;

FIGS. 10 to 13 are cross-sectional views illustrating a structure of a light emitting element according to some embodiments;

FIG. 14 is a cross-sectional view illustrating an example of the organic light emitting diode of FIG. 12 according to some embodiments;

FIG. 15 is a cross-sectional view illustrating an example of the organic light emitting diode of FIG. 13 according to some embodiments; and

FIG. 16 is a cross-sectional view illustrating a structure of a pixel of a display device according to some embodiments.

### DETAILED DESCRIPTION

Aspects and features of some embodiments of the present disclosure and methods to achieve them will become more apparent from the descriptions of the disclosed embodiments hereinbelow with reference to the accompanying drawings. However, embodiments according to the present disclosure are not limited to the disclosed embodiments disclosed herein but may be implemented in various different ways. The disclosed embodiments are provided for making the disclosure of the present disclosure thorough and for more fully conveying the scope of embodiments according to the present disclosure to those skilled in the art. It is to be noted that the scope of embodiments according to the present disclosure is defined by the appended claims, and their equivalents.

As used herein, a phrase “an element A on an element B” refers to that the element A may be located directly on the element B and/or the element A may be located indirectly on the element B via another element C. Like reference numerals denote like elements throughout the descriptions. The figures, dimensions, ratios, angles, numbers of elements given in the drawings are merely illustrative and are not limiting.

Although terms such as first, second, etc. are used to distinguish arbitrarily between the elements such terms describe, and thus these terms are not necessarily intended to indicate temporal or other prioritization of such elements. These terms are used to merely distinguish one element from another. Accordingly, as used herein, a first element may be a second element within the technical scope of the present disclosure.

Features of various embodiments of the present disclosure may be combined partially or totally. As will be clearly appreciated by those skilled in the art, technically various interactions and operations are possible. Various embodiments can be practiced individually or in combination.

Hereinafter, aspects of some embodiments of the present disclosure will be described in more detail with reference to the accompanying drawings.

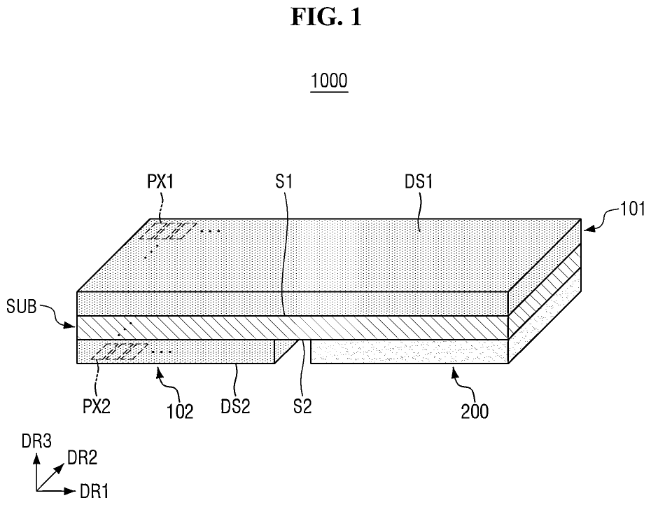

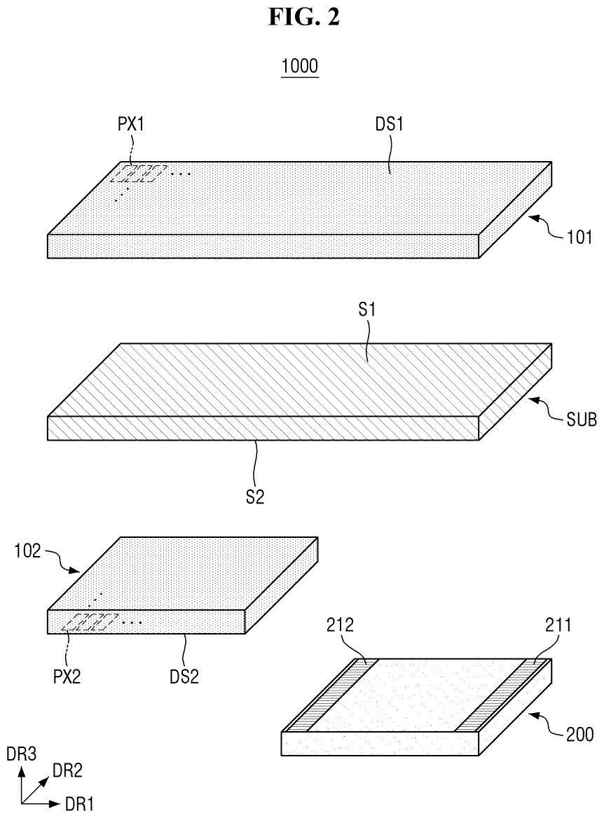

FIG. 1 is a perspective view of a display device according to some embodiments. FIG. 2 is an exploded perspective view of the display device of FIG. 1.

As shown in FIGS. 1 and 2, a display device 1000 according to some embodiments may include a substrate SUB, a first display layer 101, a second display layer 102, and a driving circuit 200.

The substrate SUB may be a rigid substrate or a flexible substrate which can be bent, folded, or rolled without damaging the substrate. The substrate SUB may be formed of an insulating material such as glass, quartz, or a polymer resin. Examples of a polymer material may include any suitable polymer material such as, for example, polyethersulphone (PES), polyacrylate (PA), polyarylate (PAR), polyetherimide (PEI), polyethylene naphthalate (PEN), polyethylene terephthalate (PET), polyphenylene sulfide (PPS), polyallylate, polyimide (PI), polycarbonate (PC), cellulose triacetate (TAC), cellulose acetate propionate (CAP), or a combination thereof. Alternatively, the substrate SUB may include a metal material.

The substrate SUB may be located between the first display layer 101 and the second display layer 102. The substrate may have a rectangular shape, but embodiments according to the present disclosure are not limited thereto. The substrate SUB may include a first surface S1 and a second surface S2 opposite to each other in a third direction DR3.

The first display layer 101 may be located on the first surface S1 of the substrate. For example, the first display layer 101 may be located on the first surface S1 of the substrate so as to overlap the entire first surface S1. The area of the first display layer 101 may be equal to or smaller than the area of the first surface S1. Here, the aforementioned area (e.g., the area of the first display layer 101 or the area of the first surface S1) may be the size in a first direction DR1 and a second direction DR2 (e.g., a size in the first direction DR1*a size in the second direction DR2).

The first display layer 101 may display images through a first display surface DS1. The first display surface DS1 of the first display layer 101 may be located on the opposite side of the interface between the first display layer 101 and the substrate SUB.

The first display layer 101 may include a plurality of first pixels PX1 for displaying an image through the aforementioned first display surface DS1. Three adjacent first pixels PX1 may constitute one first unit pixel. For example, the first unit pixel may include three first pixels PX1 located adjacent to each other in the first direction DR1 in the first display layer 101.

The three first pixels PX1 of the first unit pixel may be pixels that provide light of different colors (or wavelengths). For example, among the three first pixels PX1, one first pixel PX1 may provide light of a first color, another first pixel PX1 may provide light of a second color, and the other first pixel PX1 may provide light of a third color. Here, the first color may be any one of red, green, and blue, the second color may be any one of the above-described red, green, and blue colors different from the first color, and the third color may be any one of the above-described red, green, and blue colors different from the first color and the second color.

Additionally, the first display layer 101 may further include a plurality of gate lines, a plurality of data lines, and a plurality of emission lines connected to the above-described first pixels PX1.

The second display layer 102 may be located on the second surface S2 of the substrate SUB. For example, the second display layer 102 may be located on the second surface S2 of the substrate SUB so as to partially overlap the second surface S2. According to some embodiments, the second surface S2 may include a display area and a non-display area. The aforementioned second display layer 102 may be located in the display area of the second surface S2. The area of the second surface S2 may be the same as the area of the first surface S1 described above. The area of the second display layer 102 may be smaller than the area of the second surface S2.

The second display layer 102 may provide an image through a second display surface DS2. The second display surface DS2 of the second display layer 102 may be located on the opposite side of the interface between the second display layer 102 and the substrate SUB.

The second display layer 102 may include a plurality of second pixels PX2 for displaying an image through the aforementioned second display surface DS2. Three adjacent second pixels PX2 may constitute one second unit pixel. For example, the second unit pixel may include three second pixels PX2 located adjacent to each other in the first direction DR1 in the second display layer 102.

The three second pixels PX2 of the second unit pixel may be pixels that provide light of different colors (or wavelengths). For example, among the three second pixels PX2, one second pixel PX2 may provide light of the above-described first color, another second pixel PX2 may provide light of the above-described second color, and the other second pixel PX2 may provide light of the above-described third color.

Additionally, the second display layer 102 may further include a plurality of gate lines, a plurality of data lines, and a plurality of emission lines connected to the above-described second pixels PX2.

The driving circuit 200 may provide a plurality of gate signals, a plurality of data signals, and a plurality of emission signals for driving the first display layer 101 and the second display layer 102. The driving circuit 200 may be located on the second surface S2 of the substrate SUB. For example, the driving circuit 200 may be located in the non-display area of the second surface S2. The driving circuit 200 and the second display layer 102 may be located on the second surface S2 to be spaced apart from each other by a distance (e.g., a set or predetermined distance) in the first direction DR1.

The driving circuit 200 may include, for example, a gate driver, an emission driver, and a data driver. Meanwhile, the display device according to some embodiments may further include a circuit board on which a timing control circuit and a power supply circuit are mounted. The circuit board may be electrically connected to the second surface S2 of the substrate via a conductive adhesive member such as an anisotropic conductive film. The timing control circuit and the power supply circuit of the circuit board may be electrically connected to the driving circuit 200 through a pad of the second surface S2.

The timing control circuit may receive digital video data and timing signals from the outside. The timing control circuit may generate a gate control signal, an emission control signal, and a data control signal for controlling the display panel of the display device 1000 according to the timing signals. The timing control circuit may output the gate control signal to the gate driver and output the emission control signal to the emission driver. The timing control circuit may output the digital video data and the data control signal to the data driver.

The power supply circuit may generate a plurality of driving voltages in response to the power voltage from the outside.

Each of the timing control circuit and the power supply circuit may be formed as an integrated circuit (IC) and attached to one surface of the circuit board. The gate control signal, the emission control signal, the digital video data, and the data control signal of the timing control circuit may be supplied to the driving circuit 200 through the circuit board. The driving voltages of the power supply circuit may be supplied to the first display layer 101 and the second display layer 102 through the circuit board.

The gate driver may receive the gate control signal from the timing control circuit. The gate driver may generate gate signals according to the gate control signal of the timing control circuit and output them to the gate lines of the first display layer 101 and the gate lines of the second display layer 102, respectively.

The data driver may receive the digital video data and the data control signals from the timing control circuit. The data driver may convert the digital video data signals into analog data signals according to the data control signal and output them to the data lines of the first display layer 101 and the data lines of the second display layer 102, respectively. In this case, the first pixels PX1 of the first display layer 101 and the second pixels PX2 of the second display layer 102 may selected by the gate signal of the gate driver, and the data signals may be supplied to the selected first pixels PX1 and second pixels PX2, respectively.

The emission driver may receive the emission control signal from the timing control circuit. The emission driver may generate emission control signals according to the emission control signal and output them to the emission lines of the first display layer 101 and the emission lines of the second display layer 102, respectively.

As shown in FIG. 2, the driving circuit 200 may include a plurality of first pad terminals 211 and a plurality of second pad terminals 212. The first pad terminals 211 and the second pad terminals 212 of the driving circuit 200 may be located on one surface of the driving circuit 200 that faces the second surface S2 of the substrate SUB. The first pad terminals 211 of the driving circuit 200 may be electrically connected to the first display layer 101 through first pads of the second surface S2. Accordingly, the gate signals, the data signals, and the emission signals of the driving circuit 200 may be supplied to the first display layer 101. Additionally, the second pad terminals 212 of the driving circuit 200 may be electrically connected to the second display layer 102 through second pads of the second surface S2. Accordingly, the gate signals, the data signals, and the emission signals of the driving circuit 200 may be supplied to the second display layer 102.

According to some embodiments, the first display layer 101 and the second display layer 102 may be formed on one substrate SUB. In other words, because the first display layer 101 and the second display layer 102 are arranged respectively on both surfaces of the substrate SUB, two display layers 101 and 102 may be located on one substrate SUB. Accordingly, the display device 1000 including two display layers 101 and 102 may have a small thickness. In addition, because one substrate SUB may be used in manufacturing the display device 1000 including the two display layers 101 and 102, the manufacturing cost of the display device 1000 may be relatively reduced.

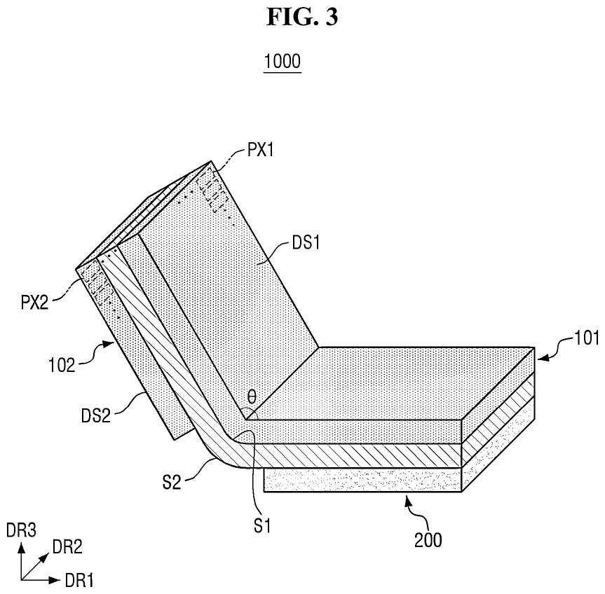

FIG. 3 is a diagram showing the display device 1000 of FIG. 1 in a folded state at a specific angle.

As shown in FIG. 3, the display device 1000 may be folded at a specific angle θ. For example, the center portion of the substrate SUB and the first display layer 101 is folded at the specific angle θ, so that the display device 1000 may be folded at the specific angle θ.

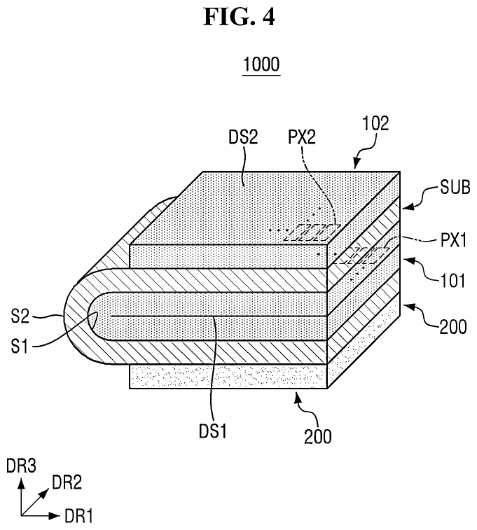

FIG. 4 is a diagram showing the display device 1000 of FIG. 1 in a completely folded state.

As shown in FIG. 4, the display device 1000 may be folded at an angle of 180 degrees such that the second display surface DS2 of the second display layer 102 faces the third direction. For example, the center portion of the substrate SUB and the first display layer 101 is folded at an angle of 180 degrees, so that the display device may be folded at the angle of 180 degrees. In this case, because the first display surface DS1 of the first display layer 101 may be divided into a first sub-display surface overlapping the second display layer 102 and a second sub-display surface overlapping the driving circuit 200, the first sub-display surface and the second sub-display surface may be arranged to face each other as shown in FIG. 4.

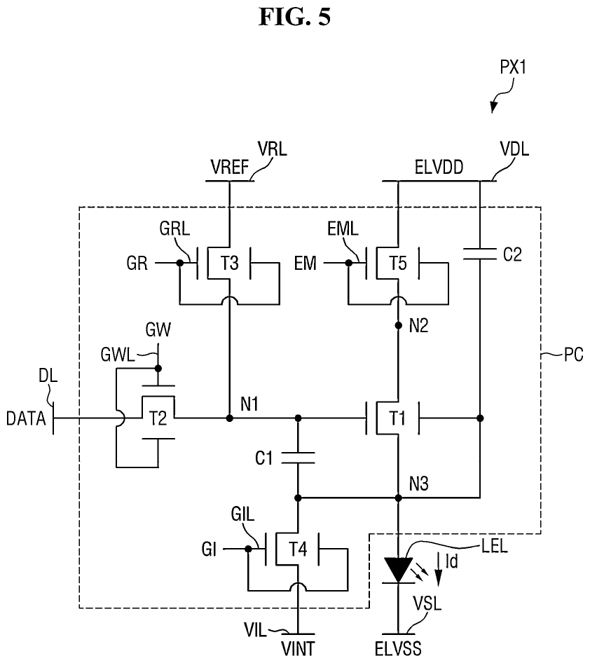

FIG. 5 is an equivalent circuit diagram of the first pixel PX1 provided in the first display layer 101 of FIG. 1.

Referring to FIG. 5, the first pixel PX1 may include a light emitting element LEL (e.g., an organic light emitting diode) as a display element and a pixel circuit PC connected to the light emitting element LEL. The pixel circuit PC may include first to fifth transistors T1 to T5 and first and second capacitors C1 and C2.

The first transistor T1 may be a driving transistor in which a size of a source-drain current is determined according to a gate-source voltage, and the second to fifth transistors T2 to T5 may be a switching transistor that is turned on/off according to the gate-source voltage, substantially a gate voltage. The first to fifth transistors T1 to T5 may be implemented as thin film transistors. According to the type (p-type or n-type) and/or the operating condition of the transistor, the first electrode of each of the first to fifth transistors T1 to T5 may be a source electrode or a drain electrode, and the second electrode may be an electrode different from the first electrode. For example, when the first electrode is a source electrode, the second electrode may be a drain electrode.

The pixel PX may be connected to a first gate line GWL that transmits a first gate signal GW, a second gate line GIL that transmits a second gate signal GI, a third gate line GRL that transmits a third gate signal GR, an emission line EML that transmits an emission signal EM, and a data line DL that transmits a data signal DATA. A driving voltage line VDL may transmit a driving voltage ELVDD to the fifth transistor T5. An initialization voltage line VIL may transmit an initialization voltage VINT to the fourth transistor T4. A reference voltage line VRL may transmit the reference voltage VREF to the third transistor T3. Meanwhile, depending on the pixel structure, the initialization voltage line VIL described above may include a plurality of initialization voltage lines (e.g., a first initialization voltage line and a second initialization voltage line) that transmit initialization voltages of different sizes.

A plurality of first to fifth transistors T1 to T5 may include an oxide semiconductor material. Because the oxide semiconductor has high carrier mobility and low leakage current, the voltage drop is not large although the driving time is long. That is, in the case of an oxide semiconductor, because a color change of an image due to a voltage drop is not large even during low-frequency driving, low-frequency driving is possible. Accordingly, a display device preventing or reducing the generation of leakage current and having relatively reduced power consumption may be implemented by the plurality of first to fifth transistors T1 to T5 including an oxide semiconductor material. In addition, in the case of using an oxide semiconductor transistor, a crystallization process by excimer laser annealing (ELA) is not required to form a low-temperature polycrystaline silicon (LTPS) semiconductor transistor, and thus the manufacturing cost of the display device 1000 may be relatively reduced, so that it may enable implementation of a large-area display device.

The oxide semiconductor is sensitive to light, so that a fluctuation in current amount and the like may occur due to light from the outside. Accordingly, it may be considered to absorb or reflect light from the outside by positioning a metal layer under the oxide semiconductor. The metal layer positioned below the oxide semiconductor of each of the first to fifth transistors T1 to T5 may function as a counter gate electrode. That is, the first to fifth transistors T1 to T5 may be double gate transistors having two gate electrodes (e.g., a first gate electrode GE1 and a second gate electrode GE2, or a gate electrode and a counter gate electrode). The first gate electrode GE1 and the second gate electrode GE2 may be arranged to face each other on different layers. For example, each of the first to fifth transistors T1 to T5 may be an N-channel oxide semiconductor transistor, and the first gate electrode GE1 and the second gate electrode GE2 of each of the first to fifth transistors T1 to T5 may be positioned to face each other with an oxide semiconductor interposed therebetween.

The first transistor T1 includes the first gate electrode GE1 connected to a first node N1 (or gate node), the second gate electrode GE2 connected to a third node N3, a first electrode connected to a second node N2, and a second electrode connected to the third node N3. The second gate electrode GE2 of the first transistor T1 may be connected to the second electrode of the first transistor T1 to be controlled by a voltage applied to the second electrode of the first transistor T1, and may relatively improve the output saturation characteristics of the first transistor T1. The first electrode of the first transistor T1 may be connected to the driving voltage line VDL via the fifth transistor T5, and the second electrode may be connected to the pixel electrode of the light emitting element LEL. The first transistor T1 may serve as a driving transistor, and may control the magnitude (e.g., current amount) of a driving current Id flowing to the light emitting element LEL by receiving the data signal DATA according to the switching operation of the second transistor T2.

The second transistor T2 includes the first gate electrode GE1 and the second gate electrode GE2 connected to the first gate line GWL, a first electrode connected to the data line DL, and a second electrode connected to the first node N1 (or the gate electrode of the first transistor T1). The second transistor T2 may be turned on according to the first gate signal GW transmitted to the first gate line GWL to electrically connect the data line DL to the first node N1, and may transmit the data signal DATA transmitted to the data line DL to the first node N1.

The third transistor T3 may include the first gate electrode GE1 and the second gate electrode GE2 connected to the third gate line GRL, a first electrode connected to the reference voltage line VRL, and a second electrode connected to the first node N1 (or the gate electrode of the first transistor T1). The third transistor T3 may be turned on according to the third gate signal GR transmitted to the third gate line GRL and transmit the reference voltage VREF transmitted to the reference voltage line VRL to the first node N1.

The fourth transistor T4 includes the first gate electrode GE1 and the second gate electrode GE2 connected to the second gate line GIL, a first electrode connected to the third node N3 (or the second electrode of the first transistor T1), and a second electrode connected to the initialization voltage line VIL. The fourth transistor T4 may be turned on according to the second gate signal GI transmitted to the second gate line GIL and transmit the initialization voltage VINT transmitted to the initialization voltage line VIL to the third node N3.

The fifth transistor T5 may include the first gate electrode GE1 and the second gate electrode GE2 connected to the emission line EML, a first electrode connected to the driving voltage line VDL, and a second electrode connected to the second node (or the first electrode of the first transistor T1). The fifth transistor T5 may be turned on or off according to the emission signal EM transmitted to the emission line EML.

The first capacitor C1 may be connected between the first node N1 and the third node N3. The first electrode of the first capacitor C1 may be connected to the gate electrode of the first transistor T1, and the second terminal thereof may be connected to the second gate electrode GE2 and the second electrode of the first transistor T1, the first electrode of the fourth transistor T4, and the pixel electrode (e.g., anode electrode) of the light emitting element LEL. The first capacitor C1 may be a storage capacitor and may store a voltage corresponding to a threshold voltage and a data signal of the first transistor T1.

The second capacitor C2 may be connected between the third node N3 and the driving voltage line VDL. The first electrode of the second capacitor C2 may be connected to the driving voltage line VDL, and the second electrode thereof may be connected to the second gate electrode GE2 and the second electrode of the first transistor T1, the second electrode of the first capacitor C1, the first electrode of the fourth transistor T4, and the pixel electrode of the light emitting element LEL. The capacitance of the first capacitor C1 may be greater than the capacitance of the second capacitor C2.

The light emitting element LEL may include a pixel electrode (e.g., an anode electrode) and a counter electrode (e.g., a cathode electrode) facing the pixel electrode, and the counter electrode may be applied with a common voltage ELVSS. The counter electrode may be connected to a common voltage line VSL transmitting a common voltage EVLSS. The counter electrode may be a common electrode CM commonly shared by the plurality of pixels PX.

Although FIG. 5 illustrates various components in a pixel circuit, embodiments according to the present disclosure are not limited thereto. For example, according to some embodiments, the pixel circuit may include additional components or fewer components without departing from the spirit and scope of embodiments according to the present disclosure.

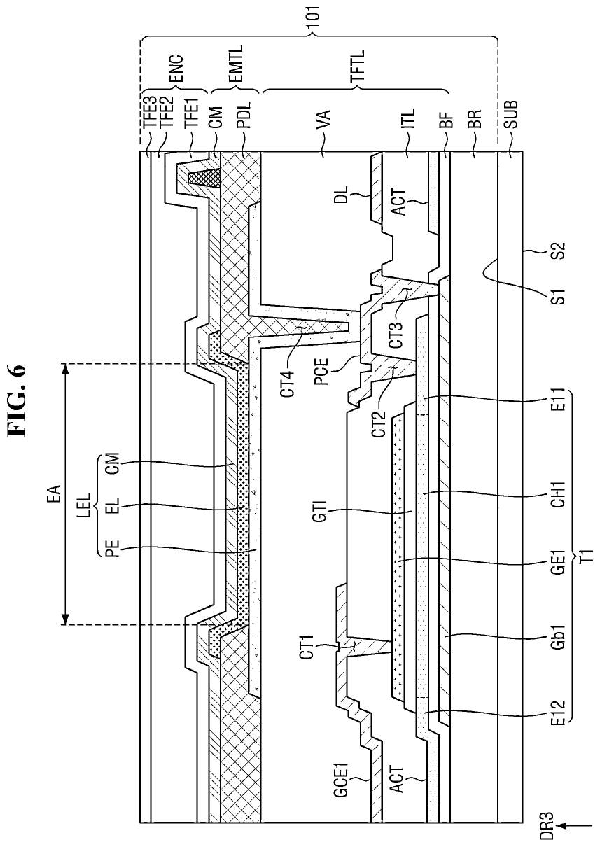

FIG. 6 is a cross-sectional view of the first display layer 101 of FIG. 1.

As shown in FIG. 6, the first display layer 101 may include a barrier layer BR, a thin film transistor layer TFTL, a light emitting element layer EMTL, and an encapsulation layer ENC that are located on the first surface S1 of the substrate SUB along the third direction DR3. In other words, the barrier layer BR, the thin film transistor layer TFTL, the light emitting element layer EMTL, and the encapsulation layer ENC may be sequentially located on the first surface S1 of the substrate SUB along the third direction DR3.

The first gate line GWL, the second gate line GIL, the third gate line GRL, a first lower capacitor electrode of the first capacitor C1, a first counter gate electrode Gb1 of the first transistor, the emission line EML, a first lower driving voltage line of the driving voltage line VDL, a first lower initialization voltage line of the initialization voltage line VIL, and a second lower initialization voltage line of the initialization voltage line may be located on the barrier layer BR. FIG. 6 illustrates an example in which the first counter gate electrode Gb1 of the first transistor T1 is located on the barrier layer BR.

A buffer layer BF may be located on the first gate line GWL, the second gate line GIL, the third gate line GRL, the first lower capacitor electrode of the first capacitor C1, the first counter gate electrode Gb1 of the first transistor T1, the emission line EML, the first lower driving voltage line of the driving voltage line VDL, the first lower initialization voltage line of the initialization voltage line VIL, and the second lower initialization voltage line of the initialization voltage line VIL described above. The buffer layer BF may be a layer for protecting transistors of the thin film transistor layer TFTL and a light emitting layer EL of the light emitting element layer EMTL from moisture permeating through the substrate SUB which is susceptible to moisture permeation. The buffer layer BF may be formed of a plurality of inorganic layers that are alternately stacked. For example, the buffer layer BF may be formed of multiple layers in which one or more inorganic layers of a silicon nitride layer, a silicon oxynitride layer, a silicon oxide layer, a titanium oxide layer and an aluminum oxide layer are alternately stacked.

An active layer ACT of the first to fifth transistors T1 to T5 may be located on the buffer layer BF. FIG. 6 illustrates an example in which the active layer ACT of the first transistor T1 is located on the barrier layer BR. The active layer ACT may include a first channel region CH1, a first electrode (e.g., E11), and a second electrode (e.g., E12) of the first transistor T1. The active layer ACT may include an oxide semiconductor material.

A gate insulating layer GTI may be located on the active layer ACT. The gate insulating layer GTI may include at least one of tetraethylorthosilicate (TEOS), silicon nitride (SiNx), or silicon oxide (SiO₂). For example, the gate insulating layer GTI may have a double layer structure in which a silicon nitride layer having a thickness of 40 nm and a tetraethylorthosilicate layer having a thickness of 80 nm are sequentially stacked.

The first gate electrode GE1 of the first transistor T1, the second gate electrode of the second transistor T2, the third gate electrode of the third transistor T3, the fourth gate electrode of the fourth transistor T4, the fifth gate electrode of the fifth transistor T5, and a lower reference voltage line of the reference voltage line VRL may be located on the gate insulating layer GTI. FIG. 6 illustrates an example in which the first gate electrode GE1 of the first transistor is located on the gate insulating layer GTI. The first gate electrode GE1 may be located on the gate insulating layer GTI to overlap the active layer ACT and the first counter gate electrode Gb1. The first channel region CH1 may be located in one region of the active layer ACT that overlaps the first gate electrode GE1. Meanwhile, the gate insulating layer GTI described above may have the same shape as the first gate electrode GE1, but may have a larger area than that of the first gate electrode GE1.

An interlayer insulating layer ITL may be located on the first gate electrode GE1, the second gate electrode, the third gate electrode, the fourth gate electrode, the fifth gate electrode, and the lower reference voltage line of the reference voltage line VRL. The interlayer insulating layer ITL may have a thickness greater than that of the gate insulating layer GTI. Here, the thickness may mean the size in the third direction DR3. The interlayer insulating layer ITL may include an inorganic layer, for example, a silicon nitride layer, a silicon oxynitride layer, a silicon oxide layer, a titanium oxide layer, or an aluminum oxide layer. Meanwhile, the interlayer insulating layer ITL may include a plurality of inorganic layers.

The data line DL, an upper driving voltage line of the driving voltage line VDL, a pixel connection electrode PCE, and a gate connection electrode connected to each gate electrode may be located on the interlayer insulating layer ITL. FIG. 6 illustrates an example in which the data line DL, the pixel connection electrode PCE, and a first gate connection electrode GCE1 are located on the interlayer insulating layer ITL. The first gate connection electrode GCE1 may be connected to the first gate electrode G1 of the first transistor T1 through a first contact hole CT1 penetrating the interlayer insulating layer ITL. One side of the pixel connection electrode PCE may be connected to the first electrode E11 of the first transistor T1 through a second contact hole CT2 penetrating the interlayer insulating layer ITL, and the other side of the pixel connection electrode PCE may be connected to the first counter gate electrode Gb1 of the first transistor T1 through a third contact hole CT3 penetrating the interlayer insulating layer ITL and the buffer layer BF.

A planarization layer VA may be located on the data line DL, the upper driving voltage line of the driving voltage line VDL, the pixel connection electrode PCE, and the gate connection electrode connected to each gate electrode. The planarization layer VA may include an organic layer such as acryl resin, epoxy resin, phenolic resin, polyamide resin, polyimide resin and the like.

The light emitting element layer EMTL may be located on the planarization layer VA. For example, the light emitting element layer EMTL may be located on the thin film transistor layer TFTL. The light emitting element layer EMTL may include the light emitting element LEL and a pixel defining layer PDL.

The light emitting element LEL may include the pixel electrode PE, the light emitting layer EL, and the common electrode CM. An emission area EA, in which the pixel electrode PE, the light emitting layer EL, and the common electrode CM are sequentially stacked, indicates an area in which holes from the pixel electrode PE and electrons from the common electrode CM are combined with each other in the light emitting layer to emit light. In this case, the pixel electrode PE may be the anode electrode of the light emitting element LEL, and the common electrode CM may be the cathode electrode of the light emitting element LEL.

The pixel electrode PE may be located on the planarization layer VA. The pixel electrode PE may be connected to the pixel connection electrode PCE through a fourth contact hole CT4 penetrating the planarization layer VA.

In a top emission structure that emits light toward the common electrode CM with respect to the light emitting layer EL, the pixel electrode PE may be formed of a single layer of molybdenum (Mo), titanium (Ti), copper (Cu), or aluminum (AI), or may be formed to have a stacked structure (Ti/Al/Ti) of aluminum and titanium, a stacked structure (ITO/AI/ITO) of aluminum and ITO, an APC alloy, or a stacked structure (ITO/APC/ITO) of APC alloy and ITO to increase the reflectivity. The APC alloy may be an alloy of silver (Ag), palladium (Pd) and copper (Cu).

The pixel defining layer PDL serves to define the emission areas EA of the first pixels PX1. To this end, the pixel defining layer PDL may be arranged to expose a partial area of the pixel electrode PE on the planarization layer VA. The pixel defining layer PDL may cover an edge of the pixel electrode PE. The pixel defining layer PDL may be located in the fourth contact hole CT4 penetrating the planarization layer VA. Accordingly, the fourth contact hole CT4 penetrating the planarization layer VA may be filled by the pixel defining layer PDL. The pixel defining layer PDL may be formed of an organic layer such as acryl resin, epoxy resin, phenolic resin, polyamide resin, polyimide resin and the like.

The spacer SPC may be located on the pixel defining layer PDL. The spacer SPC may serve to support a mask during a process of manufacturing the light emitting layer EL. The spacer SPC may be formed of an organic layer such as acryl resin, epoxy resin, phenolic resin, polyamide resin, polyimide resin and the like. The light emitting layer EL may be formed on the pixel electrode PE. The

light emitting layer EL may include an organic material to emit light in a color (e.g., a set or predetermined color). For example, the light emitting layer EL may include a hole transporting layer, an organic material layer, and an electron transporting layer. The organic material layer may include a host and a dopant. The organic material layer may include a material that emits light (e.g., a set or predetermined light), and may be formed using a phosphorescent material or a fluorescent material.

For example, the organic material layer of the first light emitting layer of the first emission area emitting the light of the first color may be a phosphorescent material including a host material including carbazole biphenyl (CBP) or mCP (1,3-bis(carbazol-9-yl), and a dopant including at least one selected from the group consisting of PIQIr(acac)(bis(1-phenylisoquinoline)acetylacetonate iridium), PQIr(acac)(bis(1-phenylquinoline)acetylacetonate iridium), PQIr(tris(1-phenylquinoline)iridium)) and PtOEP (octaethylporphyrin platinum). Alternatively, the organic material layer of the first light emitting layer of the first emission area may be a fluorescent material including PBD: Eu(DBM)3(Phen) or Perylene, but the present disclosure is not limited thereto.

The organic material layer of the second light emitting layer of the second emission area emitting the light of the second color may be a phosphorescent material including a host material including CBP or mCP, and a dopant material including Ir(ppy)3(fac tris(2-phenylpyridine)iridium. Alternatively, the organic material layer of the second light emitting layer of the second emission area emitting the light of the second color may be a fluorescent material including tris(8-hydroxyquinolino)aluminum (Alq3), but the present disclosure is not limited thereto.

The organic material layer of the light emitting layer of the third emission area emitting the light of the third color may be a phosphorescent material including a host material including CBP or mCP, and a dopant material including (4,6-F2ppy) 2Irpic or L2BD111, but the present disclosure is not limited thereto.

The common electrode CM may be arranged on the light emitting layer EL. The common electrode CM may be arranged to cover the light emitting layer EL. The common electrode CM may be a common layer that is commonly arranged in the light emitting layers EL of the first pixels PX1. According to some embodiments, a capping layer may be formed on the common electrode CM.

In the top emission structure, the common electrode CM may be formed of a transparent conductive material (TCO) such as ITO or IZO capable of transmitting light or a semi-transmissive conductive material such as magnesium (Mg), silver (Ag), or an alloy of magnesium (Mg) and silver (Ag). When the common electrode CM is formed of a semi-transmissive conductive material, the light emission efficiency can be increased due to a micro-cavity effect.

The encapsulation layer ENC may be located on the light emitting element layer EMTL. The encapsulation layer ENC may include at least one inorganic layer TFE1 and TFE3 to prevent or reduce instances of contaminants such as oxygen or moisture permeating into the light emitting element layer EMTL. In addition, the encapsulation layer ENC may include at least one organic layer to protect the light emitting element layer EMTL from foreign substances such as dust. For example, the encapsulation layer ENC may include a first encapsulation inorganic layer TFE1, an encapsulation organic layer TFE2, and a second encapsulation inorganic layer TFE3.

The first encapsulation inorganic layer TFE1 may be located on the common electrode CM, the encapsulation organic layer TFE2 may be located on the first encapsulation inorganic layer TFE1, and the second encapsulation inorganic layer TFE3 may be located on the encapsulation organic layer TFE2. The first encapsulation inorganic layer TFE1 and the second encapsulation inorganic layer TFE3 may be formed of a multilayer in which one or more inorganic layers of a silicon nitride layer, a silicon oxynitride layer, a silicon oxide layer, a titanium oxide layer and an aluminum oxide layer are alternately stacked. The encapsulation organic layer TFE2 may be an organic layer such as acryl resin, epoxy resin, phenolic resin, polyamide resin, polyimide resin or the like.

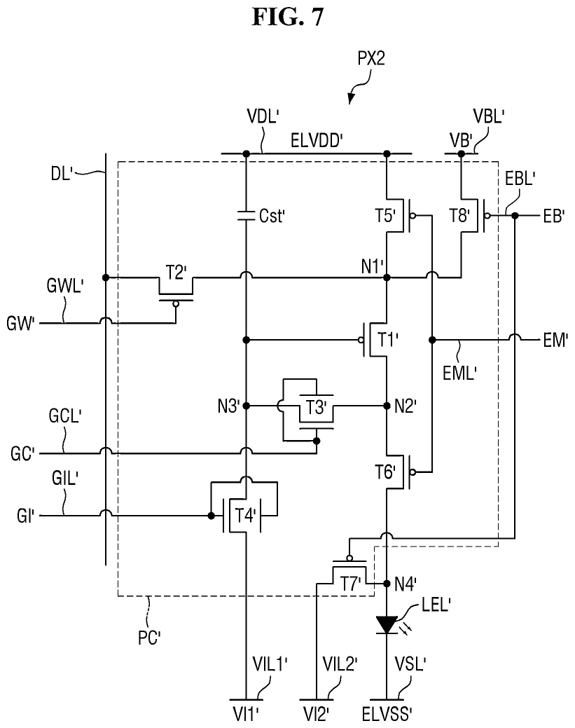

FIG. 7 is an equivalent circuit diagram of the second pixel PX2 provided in the second display layer 102 of FIG. 1.

Referring to FIG. 7, the second pixel PX2 may be connected to a first gate line GWL′, a second gate line GCL′, a third gate line GIL′, a fourth gate line EBL′, an emission line EML′, a data line DL′, a driving voltage line VDL′, a common voltage line VSL′, a first initialization voltage line VIL1′, a second initialization voltage line VIL2′, and a bias voltage line VBL′.

The second pixel PX2 may include a pixel circuit PC′ and a light emitting element LEL′. The pixel circuit PC′ may include a first transistor T1′, a second transistor T2′, a third transistor T3′, a fourth transistor T4′, a fifth transistor T5′, a sixth transistor T6′, a seventh transistor T7′, an eighth transistor T8′, and a capacitor Cst′.

The first transistor T1′ may include a gate electrode, a source electrode, and a drain electrode. The first transistor T1′ may control a source-drain current (hereinafter, a driving current) according to the data signal applied to the gate electrode. The driving current (e.g., Isd) flowing through a channel region of the first transistor T1′ may be proportional to the square of a difference between the threshold voltage Vth and the voltage Vsg between the source electrode and the gate electrode of the first transistor T1′(Isd=k×(Vsg−Vth)²). Here, k is a proportional coefficient determined by the structure and physical characteristics of the first transistor T1′, Vsg is a source-gate voltage of the first transistor T1′, and Vth is a threshold voltage of the first transistor T1′.

The light emitting element LEL′ may emit light by receiving the driving current Isd. The emission amount or the luminance of the light emitting element LEL′ may be proportional to the magnitude of the driving current Isd.

The light emitting element LEL′ may be an organic light emitting diode including a first electrode, a second electrode, and an organic light emitting layer located between the first electrode and the second electrode. For another example, the light emitting element LEL′ may be an inorganic light emitting element including a first electrode, a second electrode, and an inorganic semiconductor located between the first electrode and the second electrode. For still another example, the light emitting element LEL′ may be a quantum dot light emitting element including a first electrode, a second electrode, and a quantum dot light emitting layer located between the first electrode and the second electrode. For still another example, the light emitting element LEL′ may be a micro light emitting diode.

The first electrode of the light emitting element LEL′ may be electrically connected to the fourth node N4′. The first electrode of the light emitting element LEL′ may be connected to the drain electrode of the sixth transistor T6′ and the source electrode of the seventh transistor T7′ through the fourth node N4′. The second electrode of the light emitting element LEL′ may be connected to the common voltage line VSL′. The second electrode of the light emitting element LEL′ may receive a common voltage ELVSS′ (e.g., low potential voltage) from the common voltage line VSL′.

The second transistor T2′ may be turned on by the first gate signal GW of the first gate line GWL′ to electrically connect the data line DL′ with a first node N1′ that is the source electrode of the first transistor T1′. The second transistor T2′ may be turned on according to the first gate signal to supply the data signal to the first node N1′. The gate electrode of the second transistor T2′ may be electrically connected to the first gate line GWL′, the source electrode thereof may be electrically connected to the data line DL′, and the drain electrode thereof may be electrically connected to the first node N1′.

The third transistor T3′ may be turned on by a second gate signal GC of the second gate line GCL′ to electrically connect the second node N2′, which is the drain electrode of the first transistor T1′, to the third node N3′, which is the gate electrode of the first transistor T1′. The third transistor T3′ may be connected between the third node N3′ and the second node N2′. For example, the gate electrode of the third transistor T3′ may be electrically connected to the second gate line GCL′, the source electrode thereof may be electrically connected to the third node N3′, and the drain electrode thereof may be electrically connected to the second node N2′. The third transistor T3′ may be turned on by the second gate signal GC of the second gate line GCL′ to electrically connect the second node N2′, which is the drain electrode of the first transistor T1′, to the third node N3′, which is the gate electrode of the first transistor T1′. The third transistor T3′ may be a double gate transistor having two gate electrodes (e.g., a gate electrode and a counter gate electrode). The gate electrode and the counter gate electrode may be arranged to face each other on different layers.

The fourth transistor T4′ may be turned on by a third gate signal GI′ of the third gate line GIL′ to electrically connect the third node N3′, which is the gate electrode of the first transistor T1′, to the first initialization voltage line VIL1′. The fourth transistor T4′ may be connected in series between the third node N3′ and the first initialization voltage line VIL1′. For example, the gate electrode of the fourth transistor T4′ may be electrically connected to the third gate line GIL′, the source electrode thereof may be electrically connected to the third node N3′, and the drain electrode thereof may be electrically connected to the first initialization voltage line VIL1′. The fourth transistor T4′ may be a double gate transistor. The first initialization voltage line VIL1′ may transmit a first initialization voltage VI1′.

The fifth transistor T5′ may be turned on by an emission signal EM′ of the emission line EML′ to electrically connect the driving voltage line VDL′ with the first node N1′ that is the source electrode of the first transistor T1′. The gate electrode of the fifth transistor T5′ may be electrically connected to the emission line EML′, the source electrode thereof may be electrically connected to the driving voltage line VDL′, and the drain electrode thereof may be electrically connected to the first node N1′.

The sixth transistor T6′ may be turned on by the emission signal EM′ of the emission line EML′ to electrically connect the second node N2′ that is the drain electrode of the first transistor T1′ with the fourth node N4′ that is the first electrode of the light emitting element LEL′. The gate electrode of the sixth transistor T6′ may be electrically connected to the emission line EML′, the source electrode thereof may be electrically connected to the second node N2′, and the drain electrode thereof may be electrically connected to the fourth node N4′.

When all of the fifth transistor T5′, the first transistor T1′, and the sixth transistor T6′ are turned on, the driving current may be supplied to the light emitting element LEL′.

The seventh transistor T7′ may be turned on by a fourth gate signal EB′ of the fourth gate line EBL′ to electrically connect the fourth node N4′ that is the first electrode of the light emitting element LEL′ with the second initialization voltage line VIL2′. By turning on the seventh transistor T7′ based on the fourth gate signal EB′, the first electrode of the light emitting element LEL′ may be discharged to a second initialization voltage VI2′. The gate electrode of the seventh transistor T7′ may be electrically connected to the fourth gate line EBL′, the source electrode thereof may be electrically connected to the fourth node N4′, and the drain electrode thereof may be electrically connected to the second initialization voltage line VIL2′. The second initialization voltage line VIL2′ may transmit the second initialization voltage VI2′.

The eighth transistor T8′ may be turned on by the fourth gate signal EB′ of the fourth gate line EBL′ to electrically connect the bias voltage line VBL′ with the first node N1′ that is the source electrode of the first transistor T1′. The eighth transistor T8′ may be turned on according to the fourth gate signal EB′ to supply a bias voltage VB′ to the first node N1′. The eighth transistor T8′ may relatively improve hysteresis of the first transistor T1′ by supplying the bias voltage VB′ to the source electrode of the first transistor T1′. The gate electrode of the eighth transistor T8′ may be electrically connected to the fourth gate line EBL′, the source electrode thereof may be electrically connected to the bias voltage line VBL′, and the drain electrode thereof may be electrically connected to the first node N1′.

Each of the first transistor T1′, the second transistor T2′, the fifth transistor T5′, the sixth transistor T6′, the seventh transistor T7′, and the eighth transistor T8′ may include a silicon-based active layer (or semiconductor layer). For example, each of the first transistor T1′, the second transistor T2′, the fifth transistor T5′, the sixth transistor T6′, the seventh transistor T7′, and the eighth transistor T8′ may be a p-type transistor including an active layer made of low temperature polycrystalline silicon (LTPS). The active layer made of low temperature polycrystalline silicon may have high electron mobility and excellent turn-on characteristics. Accordingly, in the display device 10, since the transistors having excellent turn-on characteristics are included, it is possible to stably and efficiently drive the plurality of second pixels PX2. Each of the first transistor T1′, the second transistor T2′, the fifth transistor T5′, the sixth transistor T6′, the seventh transistor T7′, and the eighth transistor T8′ may output a current flowing into the source electrode to the drain electrode based on a gate low voltage applied to the gate electrode.

The third transistor T3′ and the fourth transistor T4′ may be n-type transistors including an oxide-based active layer (or semiconductor layer). The transistor including the oxide-based active layer may have a coplanar structure in which a gate electrode is located thereon. The transistor including the oxide-based active layer may output a current flowing into the drain electrode to the source electrode based on a gate high voltage applied to the gate electrode.

The capacitor Cst′ may be electrically connected between the third node N3′ that is the gate electrode of the first transistor T1′ and the driving voltage line VDL′. For example, the first electrode of the capacitor Cst′ may be electrically connected to the third node N3′, and the second electrode of the capacitor Cst′ may be electrically connected to the driving voltage line VDL′, so that a potential difference between the driving voltage line VDL′ and the gate electrode of the first transistor T1′ may be maintained.

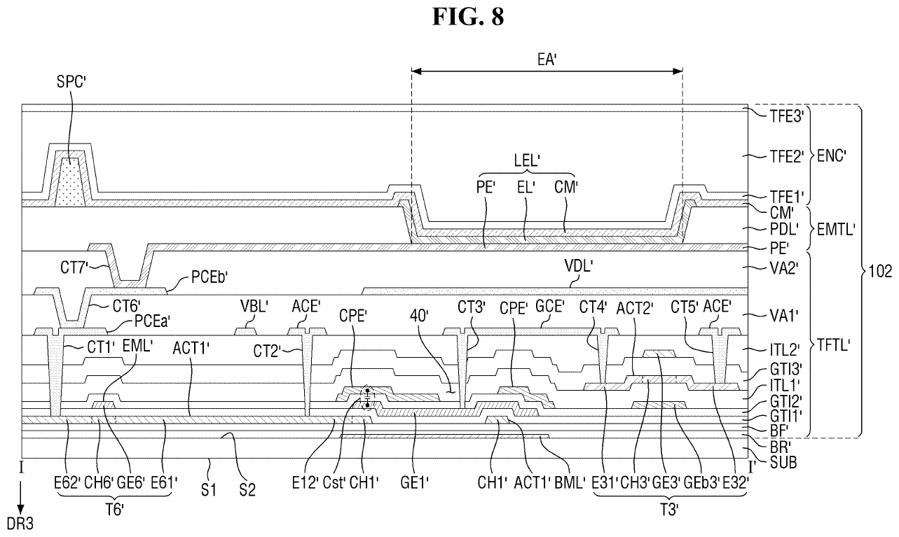

Although FIG. 8 illustrates various components of a pixel circuit according to some embodiments of the present disclosure, embodiments are not limited thereto. For example, according to some embodiments the pixel circuit may include additional components or fewer components without departing from the spirit and scope of embodiments according to the present disclosure.

FIG. 8 is a cross-sectional view of the second display layer 102 of FIG. 1.

As shown in FIG. 8, the second display layer 102 may include a barrier layer BR′, a thin film transistor layer TFTL′, a light emitting element layer EMTL′, and an encapsulation layer ENC′ that are located on the second surface S2 of the substrate SUB along the reverse direction of the third direction DR3 (hereinafter, referred to as a third reverse direction). In other words, the barrier layer BR′, the thin film transistor layer TFTL′, the light emitting element layer EMTL′, and the encapsulation layer ENC″ may be sequentially located on the second surface S2 of the substrate SUB along the third reverse direction.

The barrier layer BR′ may be located on the substrate SUB. The barrier layer BR′ may be located on the entire surface of the substrate SUB. The barrier layer BR′ may be a layer for protecting the transistors T1 to T8 of the thin film transistor layer TFTL′ and a light emitting layer EL′ of the light emitting element layer EMTL′ from moisture permeating through the substrate SUB which is susceptible to moisture permeation. The barrier layer BR′ may be formed as a plurality of inorganic layers that are alternately stacked. For example, the barrier layer BR′ may be formed of multiple layers in which one or more inorganic layers of a silicon nitride layer, a silicon oxynitride layer, a silicon oxide layer, a titanium oxide layer and an aluminum oxide layer are alternately stacked.

The light blocking layer BML′ may be located on the barrier layer BR′. The light blocking layer BML′ may be located on the barrier layer BR′ to cover an overlapping area (e.g., a first channel region CH1′) between a first gate electrode GE1′ of the first transistor T1′ and a first active layer ACT1′. In other words, the light blocking layer BML′ may be located on the barrier layer BR′ to overlap the channel region CH1′ of the first transistor T1′ which is the driving transistor.

The light blocking layer BML′ may be made of, for example, a metallic material such as chromium (Cr) or molybdenum (Mo), black ink, black dye, or the like. Meanwhile, when the light blocking layer BML′ is made of a metallic material, the light blocking layer BML′ may be supplied with a constant power source. In this way, the light blocking layer BML′ is not electrically floating, and the transistor (e.g., the first transistor T1′) on the light blocking layer BML′ may have its electrical characteristics stabilized.

A buffer layer BF′ may be located on the light blocking layer BML′. The buffer layer BF′ may be located on the entire surface of the substrate SUB including the barrier layer BR′. The buffer layer BF′ may be a layer for protecting the transistors T1′ to T8′ of the thin film transistor layer TFTL′ and the light emitting layer EL′ of the light emitting element layer EMTL′ from moisture permeating through the substrate SUB which is susceptible to moisture permeation. The buffer layer BF′ may be formed of a plurality of inorganic layers that are alternately stacked. For example, the buffer layer BF′ may be formed of multiple layers in which one or more inorganic layers of a silicon nitride layer, a silicon oxynitride layer, a silicon oxide layer, a titanium oxide layer and an aluminum oxide layer are alternately stacked.

The first active layer ACT1′ may be located on the buffer layer BF′. The first active layer ACT1′ may include the first channel region CH1′ of the first transistor T1′, a second electrode E12′ of the first transistor T1′, a first electrode E61′ of the sixth transistor T6′, a second electrode E62′ of the sixth transistor T6′, and a sixth channel region CH6′ of the sixth transistor T6′. The first active layer ACT1′ may be an active layer made of low temperature polycrystalline silicon (LTPS).

The first gate insulating layer GTI1′ may be located on the first active layer ACT1′. In this case, the first gate insulating layer GTI1′ may be located on the entire surface of the substrate SUB including the first active layer ACT1′.

The first gate insulating layer GTI1′ may include at least one of tetraethylorthosilicate (TEOS), silicon nitride (SiNx), or silicon oxide (SiO₂). For example, the first gate insulating layer GTI1′ may have a double layer structure in which a silicon nitride layer having a thickness of 40 nm and a tetraethylorthosilicate layer having a thickness of 80 nm are sequentially stacked.

The second gate electrode of the second transistor T2′, the first gate electrode GE1′ of the first transistor T1′, the eighth gate electrode of the eighth transistor T8′, the emission line EML′, the fifth gate electrode of the fifth transistor T5′, and a sixth gate electrode GE6′ of the sixth transistor T6′ may be located on the first gate insulating layer GTI1′. FIG. 8 illustrates an example in which the first gate electrode GE1′, the sixth gate electrode GE6′, and the emission line EML′ are located on the first gate insulating layer GTI1′. The first gate electrode GE1′ may be located on the first gate insulating layer GTI1′ to overlap the first channel region CH1′ of the first active layer ACT1′. The sixth gate electrode GE6′ of the emission line EML′ may be located on the first gate insulating layer GTI1′ to overlap the sixth channel region CH6 of the first active layer ACT1′.

A second gate insulating layer GTI2′ may be located on the second gate electrode of the second transistor T2′, the first gate electrode GE1′ of the first transistor T1′, the eighth gate electrode of the eighth transistor T8′, the emission line EML′, the fifth gate electrode of the fifth transistor T5′ and the sixth gate electrode GE6′ of the sixth transistor T6′. For example, as shown in FIG. 8, the second gate insulating layer GTI2′ may be located on the first gate electrode GE1′, the sixth gate electrode GE6′, and the emission line EML′. In this case, the second gate insulating layer GTI2′ may be located on the entire surface of the substrate SUB including the first gate electrode GE1′, the sixth gate electrode GE6′, and the emission line EML′. The second gate insulating layer GTI2′ may include the same material and structure as the first gate insulating layer GTI1′ described above.

A fourth counter gate electrode of the fourth transistor T4′, a third counter gate electrode GEb3′ of the third transistor T3′, and a capacitor electrode CPE′ of the capacitor Cst′ may be located on the second gate insulating layer GTI2′. FIG. 8 illustrates an example in which the capacitor electrode CPE′ and the third counter gate electrode GEb3′ are located on the second gate insulating layer GTI2′. The capacitor electrode CPE′ may be located on the second gate insulating layer GTI2′ to overlap the first gate electrode GE1′. The capacitor Cst′ may be formed between the capacitor electrode CPE′ and the first gate electrode GE1′.

A first interlayer insulating layer ITL1′ may be located on the fourth counter gate electrode of the fourth transistor T4′, the third counter gate electrode GEb3′ of the third transistor T3′, and the capacitor electrode CPE′ of the capacitor Cst′. For example, as shown in FIG. 8, the first interlayer insulating layer ITL1′ may be located on the capacitor electrode CPE′ and the third counter gate electrode GEb3′. In this case, the first interlayer insulating layer ITL1′ may be located on the entire surface of the substrate SUB including the capacitor electrode CPE′ and the third counter gate electrode GEb3′. The first interlayer insulating layer ITL1′ may include an inorganic layer, for example, a silicon nitride layer, a silicon oxynitride layer, a silicon oxide layer, a titanium oxide layer, or an aluminum oxide layer. Meanwhile, the first interlayer insulating layer ITL1′ may include a plurality of inorganic layers.

The second active layer ACT2′ may be located on the first interlayer insulating layer ITL1′. As shown in FIG. 8, the second active layer ACT2′ may be located on the first interlayer insulating layer ITL1′ to overlap the third counter gate electrode GEb3′. The second active layer ACT2′ may include a first electrode E31′ of the third transistor T3′, a second electrode E32′ of the third transistor T3′, and a third channel region CH3′ of the third transistor T3′. The third channel region CH3′ of the second active layer ACT2′ may overlap the third counter gate electrode GEb3′. The second active layer ACT2′ may be an oxide-based active layer. For example, the second active layer ACT2′ may be an oxide semiconductor containing indium-gallium-zinc oxide (IGZO) or indium-gallium-zinc-tin oxide (IGZTO).

A third gate insulating layer GTI3′ may be located on the second active layer ACT2′. For example, as shown in FIG. 8, the third gate insulating layer GTI3′ may be located on the second active layer ACT2′. The third gate insulating layer GTI3′ may be located on the entire surface of the substrate SUB including the second active layer ACT2′. The third gate insulating layer GTI3′ may have the same material and structure as the first gate insulating layer GTI1′ described above.

The fourth gate electrode of the fourth transistor T4′ and a third gate electrode GE3′ of the third transistor T3′ may be located on the third gate insulating layer GTI3′. FIG. 8 illustrates an example in which the third gate electrode GE3′ is located on the third gate insulating layer GTI3′. The third gate electrode GE3′ may be arranged to overlap the third channel region CH3′ of the second active layer ACT2′.

A second interlayer insulating layer ITL2′ may be located on the fourth gate electrode and the third gate electrode GE3′. For example, as shown in FIG. 8, the second interlayer insulating layer ITL2′ may be located on the third gate electrode GE3′. The second interlayer insulating layer ITL2′ may be located on the entire surface of the substrate SUB including the third gate electrode GE3′. The second interlayer insulating layer ITL2′ may have the same material and structure as the first interlayer insulating layer ITL1′ described above.

The first initialization voltage line VIL1′, the third gate line GIL′, the data connection electrode, the first gate line GWL′, the second gate line GCL′, a gate connection electrode GCE′, an active connection electrode ACE′, the bias voltage line VBL′, a capacitor connection electrode CCE′, a lower pixel connection electrode PCEa′, the fourth gate line EBL′, and the second initialization voltage line VIL2′ may be located on the second interlayer insulating layer ITL2′. FIG. 8 illustrates an example in which the gate connection electrode GCE′, the active connection electrode ACE′, the bias voltage line VBL′, and the lower pixel connection electrode PCEa′ are located on the second interlayer insulating layer ITL2′. The lower pixel connection electrode PCEa′ may be connected to the second electrode E62′ of the sixth transistor T6′ through a first contact hole CT1′ penetrating the second interlayer insulating layer ITL2′, the third gate insulating layer GTI3′, the first interlayer insulating layer ITL1′, the second gate insulating layer GTI2′, and the first gate insulating layer GTI1′. The active connection electrode ACE′ may be connected to the second electrode of the first transistor T1′ and the first electrode E61′ of the sixth transistor T6′ through a second contact hole CT2′ penetrating the second interlayer insulating layer ITL2′, the third gate insulating layer GTI3′, the first interlayer insulating layer ITL1′, the second gate insulating layer GTI2′, and the first gate insulating layer GTI1′. Further, the active connection electrode ACE′ may be connected to the second electrode E32′ of the third transistor T3′ through a fifth contact hole CT5′ penetrating the second interlayer insulating layer ITL2′ and the third gate insulating layer GTI3′. The gate connection electrode GCE′ may be connected to the first gate electrode GE1′ through a third contact hole CT3′ penetrating the second interlayer insulating layer ITL2′, the third gate insulating layer GTI3′, the first interlayer insulating layer ITL1′, a hole 40′ of the capacitor electrode CPE′, and the second gate insulating layer GTI2′. Further, the gate connection electrode GCE′ may be connected to the first electrode E31′ of the third transistor T3′ through a fourth contact hole CT4′ penetrating the second interlayer insulating layer ITL2′ and the third gate insulating layer GTI3′.

The data connection electrode may be connected to the first electrode of the first active layer ACT1′ (e.g., the first electrode of the second transistor T2′) through a contact hole of the insulating layers.

A first planarization layer VA1′ may be located on the first initialization voltage line VIL1′, the third gate line GIL′, the data connection electrode, the first gate line GWL′, the second gate line GCL′, the gate connection electrode GCE′, the active connection electrode ACE′, the bias voltage line VBL′, the capacitor connection electrode CCE′ of the capacitor Cst′, the lower pixel connection electrode PCEa′, the fourth gate line EBL′, and the second initialization voltage line VIL2′. For example, the first planarization layer VA1′ may be located on the gate connection electrode GCE′, the active connection electrode ACE′, the bias voltage line VBL′, and the lower pixel connection electrode PCEa′. The first planarization layer VA1′ may be located on the entire surface of the substrate SUB including the gate connection electrode GCE′, the active connection electrode ACE′, the bias voltage line VBL′, and the lower pixel connection electrode PCEa′. The first planarization layer VA1′ may include an organic layer such as acryl resin, epoxy resin, phenolic resin, polyamide resin, polyimide resin and the like.

The data line DL′, the driving voltage line VDL′, and an upper pixel connection electrode PCEb′ may be located on the first planarization layer VA1′. FIG. 8 illustrates an example in which the driving voltage line VDL′ and the upper pixel connection electrode PCEb′ are located on the first planarization layer VA1′. The upper pixel connection electrode PCEb′ may be connected to the lower pixel connection electrode PCEa′ through a sixth contact hole CT6′ penetrating the first planarization layer VA1′.

A second planarization layer VA2′ may be located on the data line DL′, the driving voltage line VDL′, and the upper pixel connection electrode PCEb′. For example, the second planarization layer VA2′ may be located on the driving voltage line VDL′ and the upper pixel connection electrode PCEb′. The second planarization layer VA2′ may be located on the entire surface of the substrate SUB including the driving voltage line VDL′ and the upper pixel connection electrode PCEb′. The second planarization layer VA2′ may have the same material and structure as the first planarization layer VA1′ described above.

The light emitting element layer EMTL′ may be located on the second planarization layer VA2′. For example, as shown in FIG. 8, a pixel electrode PE′ may be located on the second planarization layer VA2′. The pixel electrode PE′ may be connected to the upper pixel connection electrode PCEb′ through a seventh contact hole CT7′ penetrating the second planarization layer VA2′.

The aforementioned light emitting element layer EMTL′ may further include the light emitting element LEL′ and a pixel defining layer PDL′ in addition to the aforementioned pixel electrode PE′.

The light emitting element LEL′ may include the pixel electrode PE′, the light emitting layer EL′, and a common electrode CM′. The emission area EA′, in which the pixel electrode PE′, the light emitting layer EL′, and the common electrode CM′ are sequentially stacked, indicates an area in which holes from the pixel electrode PE′ and electrons from the common electrode CM′ are combined with each other in the light emitting layer to emit light. In this case, the pixel electrode PE′ may be the anode electrode of the light emitting element LEL′, and the common electrode CM′ may be the cathode electrode of the light emitting element LEL′.

In a top emission structure that emits light toward the common electrode CM′ with respect to the light emitting layer EL′, the pixel electrode PE′ may be formed of a single layer of molybdenum (Mo), titanium (Ti), copper (Cu), or aluminum (AI), or may be formed to have a stacked structure (Ti/Al/Ti) of aluminum and titanium, a stacked structure (ITO/AI/ITO) of aluminum and ITO, an APC alloy, or a stacked structure (ITO/APC/ITO) of APC alloy and ITO to increase the reflectivity. The APC alloy is an alloy of silver (Ag), palladium (Pd) and copper (Cu).

The pixel defining layer PDL′ may serve to define the emission areas EA′ of the second pixels PX2. To this end, the pixel defining layer PDL′ may be arranged to expose a partial area of the pixel electrode PE′ on the second planarization layer VA2′. The pixel defining layer PDL′ may cover an edge of the pixel electrode PE′. Meanwhile, the pixel defining layer PDL′ may be located in the seventh contact hole CT7′ penetrating the second planarization layer VA2′. Accordingly, the seventh contact hole CT7′ penetrating the second planarization layer VA2′ may be filled by the pixel defining layer PDL′. The pixel defining layer PDL′ may be formed of an organic layer such as acryl resin, epoxy resin, phenolic resin, polyamide resin, polyimide resin and the like.

As shown in FIG. 8, a spacer SPC′ may be located on the pixel defining layer PDL′. The spacer SPC′ may serve to support a mask during a process of manufacturing the light emitting layer EL. The spacer SPC′ may be formed of an organic layer such as acryl resin, epoxy resin, phenolic resin, polyamide resin, polyimide resin and the like.

The light emitting layer EL′ may be formed on the pixel electrode PE′. The light emitting layer EL′ may include an organic material to emit light in a color (e.g., a set or predetermined color). For example, the light emitting layer EL′ may include a hole transporting layer, an organic material layer, and an electron transporting layer. The organic material layer may include a host and a dopant. The organic material layer may include a material that emits light (e.g., a set or predetermined light), and may be formed using a phosphorescent material or a fluorescent material.

The common electrode CM′ may be arranged on the light emitting layer EL′. The common electrode CM′ may be arranged to cover the light emitting layer EL′.

The encapsulation layer ENC′ may be formed on the light emitting element layer EMTL′. The encapsulation layer ENC′ may include at least one inorganic layer TFE1′ and TFE3′ to prevent or reduce instances of oxygen or moisture permeating into the light emitting element layer EMTL′. In addition, the encapsulation layer ENC′ may include at least one organic layer to protect the light emitting element layer EMTL′ from foreign substances such as dust. For example, the encapsulation layer ENC′ may include a first encapsulation inorganic layer TFE1′, an encapsulation organic layer TFE2′, and a second encapsulation inorganic layer TFE3′.

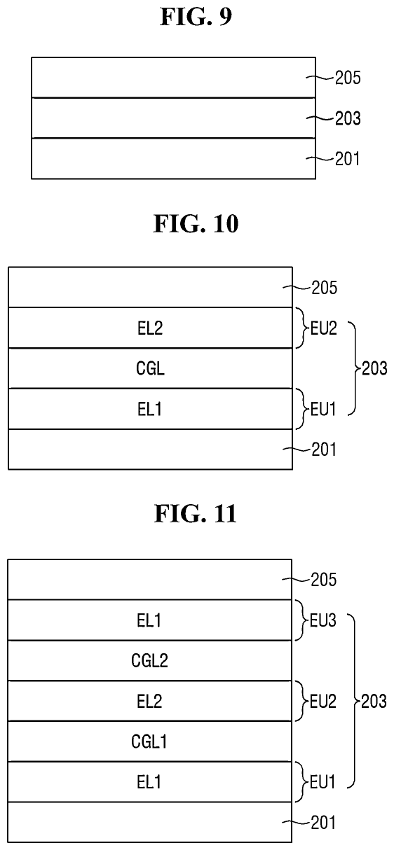

On the other hand, the above-described light emitting element (at least one of LEL or LEL′) may have a tandem structure, which will be described with reference to FIGS. 9 to 16 as follows.

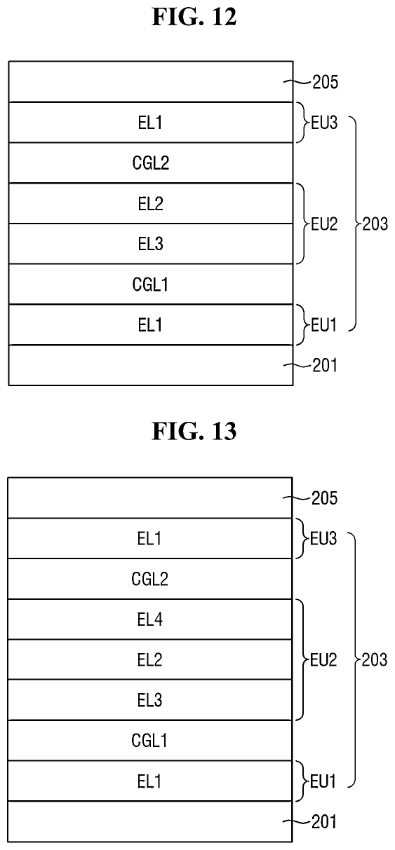

FIG. 9 is a cross-sectional view illustrating a structure of a display element according to some embodiments, and FIGS. 10 to 13 are cross-sectional views illustrating a structure of a light emitting element according to some embodiments.

Referring to FIG. 9, a light emitting element (e.g., an organic light emitting diode) according to some embodiments may include a pixel electrode 201, a common electrode 205, and an intermediate layer 203 between the pixel electrode 201 and the common electrode 205 described above.

The pixel electrode 201 may include a light-transmitting conductive oxide such as indium tin oxide (ITO), indium zinc oxide (IZO), zinc oxide (ZnO), indium oxide (In₂O₃), indium gallium oxide (IGO), or aluminum zinc oxide (AZO). The pixel electrode 201 may include a reflective layer containing silver (Ag), magnesium (Mg), aluminum (Al), platinum (Pt), palladium (Pd), gold (Au), nickel (Ni), neodymium (Nd), iridium (Ir), chromium (Cr) or a compound thereof. For example, the pixel electrode 201 may have a three-layer structure of ITO/Ag/ITO.

The common electrode 205 may be located on the intermediate layer 203. The common electrode 205 may include a low work function metal, an alloy, an electrically conductive compound, or any combination thereof. For example, the common electrode 205 may include lithium (Li), silver (Ag), magnesium (Mg), aluminum (Al), aluminum-lithium (Al—Li), calcium (Ca), magnesium-indium (Mg—In), magnesium-silver (Mg—Ag), ytterbium (Yb), silver-ytterbium (Ag—Yb), ITO, IZO, or any combination thereof. The common electrode 205 may be a transmissive electrode, a semi-transmissive electrode, or a reflective electrode.

The intermediate layer 203 may include a high molecular material or a low molecular material that emits light of a color (e.g., a set or predetermined color). In addition to various organic materials, the intermediate layer 203 may further include metal-containing compounds such as organometallic compounds, inorganic materials such as quantum dots, and the like.

According to some embodiments, the intermediate layer 203 may include one light emitting layer and a first functional layer and a second functional layer respectively located below and above the one light emitting layer. The first functional layer may include, for example, a hole transport layer HTL or may include the hole transport layer and a hole injection layer HIL. The second functional layer is a component located on the light emitting layer and is optional. For example, the intermediate layer 203 may include or may not include the second functional layer. The second functional layer may include an electron transport layer ETL and/or an electron injection layer EIL.

According to some embodiments, the intermediate layer 203 may include two or more emitting units that are sequentially stacked between the pixel electrode 201 and the common electrode 205, and a charge generation layer CGL located between the two emitting units. When the intermediate layer 203 includes an emitting unit and a charge generation layer, a light emitting element (e.g., an organic light emitting diode) may be a tandem light emitting element. A light emitting element (e.g., an organic light emitting diode) may relatively improve color purity and luminous efficiency by having a stacked structure of a plurality of emitting units.

One emitting unit may include a light emitting layer and a first functional layer and a second functional layer respectively located below and above the light emitting layer. The charge generation layer CGL may include a negative charge generation layer and a positive charge generation layer. The luminous efficiency of an organic light emitting diode, which is a tandem light emitting element having a plurality of light emitting layers, may be further increased by the negative charge generation layer and the positive charge generation layer.

The negative charge generation layer may be an n-type charge generation layer. The negative charge generation layer may supply electrons. The negative charge generation layer may include a host and a dopant. The host may include an organic material. The dopant may include a metal material. The positive charge generation layer may be a p-type charge generation layer. The positive charge generation layer may supply holes. The positive charge generation layer may include a host and a dopant. The host may include an organic material. The dopant may include a metal material.

According to some embodiments, as illustrated in FIG. 10, a light emitting element (e.g., an organic light emitting diode) may include a first emitting unit EU1 including a first light emitting layer EL1 and a second emitting unit EU2 including a second light emitting layer EL2 that are sequentially stacked. The charge generation layer CGL may be located between the first emitting unit EU1 and the second emitting unit EU2. For example, a light emitting element (e.g., an organic light emitting diode) may include the pixel electrode 201, the first light emitting layer EL1, the charge generation layer CGL, the second light emitting layer EL2, and the common electrode 205 that are sequentially stacked. The first functional layer and the second functional layer may be located on and under the first light emitting layer EL1, respectively. The first functional layer and the second functional layer may be included below and above the second light emitting layer EL2, respectively. The first light emitting layer EL1 may be a blue light emitting layer, and the second light emitting layer EL2 may be a yellow light emitting layer.

According to some embodiments, as illustrated in FIG. 11, a light emitting element (e.g., an organic light emitting diode) may include the first emitting unit EU1 and a third emitting unit EU3 including the first light emitting layer EL1, and the second emitting unit EU2 including the second light emitting layer EL2. The first charge generation layer CGL1 may be located between the first emitting unit EU1 and the second emitting unit EU2, and the second charge generation layer CGL2 may be located between the second emitting unit EU2 and the third emitting unit EU3. For example, a light emitting element (e.g., an organic light emitting diode) may include the pixel electrode 201, the first light emitting layer EL1, the first charge generation layer CGL1, the second light emitting layer EL2, the second charge generation layer CGL2, the first light emitting layer EL1, and the common electrode 205 that are sequentially stacked. The first functional layer and the second functional layer may be located on and under the first light emitting layer EL1, respectively. The first functional layer and the second functional layer may be located on and below the second light emitting layer EL2, respectively. The first light emitting layer EL1 may be a blue light emitting layer, and the second light emitting layer EL2 may be a yellow light emitting layer.

According to some embodiments, in a light emitting element (e.g., an organic light emitting diode), the second emitting unit EU2 may further include a third light emitting layer EL3 and/or a fourth light emitting layer EL4 directly in contact with the second light emitting layer EL2 below and/or above the second light emitting layer EL2, in addition to the second light emitting layer EL2. Here, direct contact may mean that no other layer is located between the second light emitting layer EL2 and the third light emitting layer EL3 and/or between the second light emitting layer EL2 and the fourth light emitting layer EL4. The third light emitting layer EL3 may be a red light emitting layer, and the fourth light emitting layer EL4 may be a green light emitting layer.

For example, as illustrated in FIG. 12, a light emitting element (e.g., an organic light emitting diode) may include the pixel electrode 201, the first light emitting layer EL1, the first charge generation layer CGL1, the third light emitting layer EL3, the second light emitting layer EL2, the second charge generation layer CGL2, the first light emitting layer EL1, and the common electrode 205 that are sequentially stacked. Alternatively, as illustrated in FIG. 13, a light emitting element (e.g., an organic light emitting diode) may include the pixel electrode 201, the first light emitting layer EL1, the first charge generation layer CGL1, the third light emitting layer EL3, the second light emitting layer EL2, the fourth light emitting layer EL4, the second charge generation layer CGL2, the first light emitting layer EL1, and the common electrode 205 that are sequentially stacked.

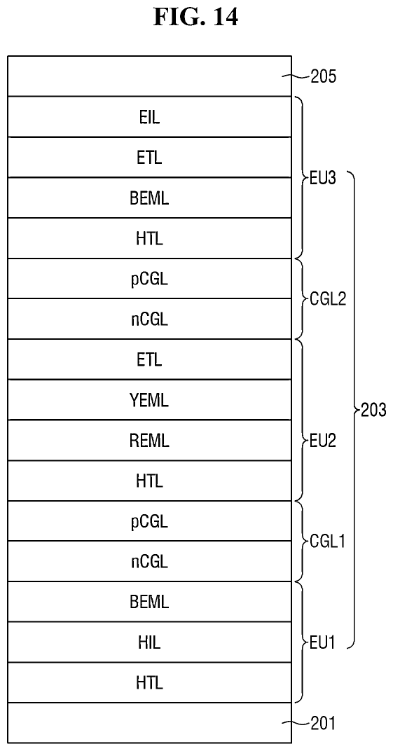

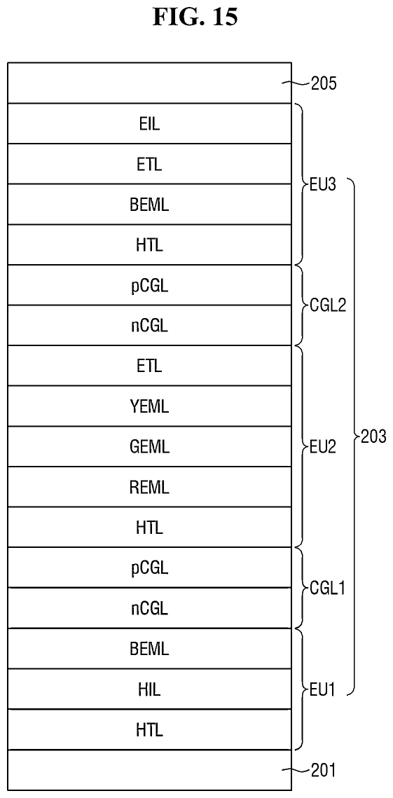

FIG. 14 is a cross-sectional view illustrating an example of the organic light emitting diode of FIG. 12, and FIG. 15 is a cross-sectional view illustrating an example of the organic light emitting diode of FIG. 13.

Referring to FIG. 14, a light emitting element (e.g., an organic light emitting diode) may include the first emitting unit EU1, the second emitting unit EU2, and the third emitting unit EU3 that are sequentially stacked. The first charge generation layer CGL1 may be located between the first emitting unit EU1 and the second emitting unit EU2, and the second charge generation layer CGL2 may be located between the second emitting unit EU2 and the third emitting unit EU3. The first charge generation layer CGL1 and the second charge generation layer CGL2 may include a negative charge generation layer nCGL and a positive charge generation layer pCGL, respectively.

The first emitting unit EU1 may include a blue light emitting layer BEML. The first emitting unit EU1 may further include the hole injection layer HIL and the hole transport layer HTL between the pixel electrode 201 and the blue light emitting layer BEML. According to some embodiments, a p-doped layer may be further included between the hole injection layer HIL and the hole transport layer HTL. The P-doped layer may be formed by doping the hole injection layer HIL with a p-type doping material. According to some embodiments, at least one of a blue light auxiliary layer, an electron blocking layer, or a buffer layer may be further included between the blue light emitting layer BEML and the hole transport layer HTL. The blue light auxiliary layer may increase light emission efficiency of the blue light emitting layer BEML. The blue light auxiliary layer may increase light emission efficiency of the blue light emitting layer BEML by adjusting hole charge balance. The electron blocking layer may prevent or reduce electron injection into the hole transport layer HTL. The buffer layer may compensate for a resonance distance according to a wavelength of light emitted from the light emitting layer.

The second emitting unit EU2 may include a yellow light emitting layer YEML and a red light emitting layer REML in direct contact with the yellow light emitting layer YEML below the yellow light emitting layer YEML. The second emitting unit EU2 may further include the hole transport layer HTL between the positive charge generation layer pCGL of the first charge generation layer CGL1 and the red light emitting layer REML, and may further include the electron transport layer ETL between the yellow light emitting layer YEML and the negative charge generation layer nCGL of the second charge generation layer CGL2.

The third emitting unit EU3 may include the blue light emitting layer BEML. The third emitting unit EU3 may further include the hole transport layer HTL between the positive charge generation layer pCGL of the second charge generation layer CGL2 and the blue light emitting layer BEML. The third emitting unit EU3 may further include the electron transport layer ETL and the electron injection layer EIL between the blue light emitting layer BEML and the common electrode 205. The electron transport layer ETL may have a single layer or a multilayer. According to some embodiments, at least one of a blue light auxiliary layer, an electron blocking layer, or a buffer layer may be further included between the blue light emitting layer BEML and the hole transport layer HTL. At least one of a hole blocking layer or a buffer layer may be further included between the blue light emitting layer BEML and the electron transport layer ETL. The hole blocking layer may prevent or reduce hole injection into the electron transport layer ETL.

A light emitting element (e.g., an organic light emitting diode) illustrated in FIG. 15 is different from the light emitting element (e.g., an organic light emitting diode) illustrated in FIG. 13 in the stacked structure of the second emitting unit EU2, and other configurations are the same. Referring to FIG. 15, the second emitting unit EU2 may include the yellow light emitting layer YEML, the red light emitting layer REML directly in contact with the yellow light emitting layer YEML below the yellow light emitting layer YEML, and a green light emitting layer GEML directly in contact with the yellow light emitting layer YEML above the yellow light emitting layer YEML. The second emitting unit EU2 may further include the hole transport layer HTL between the positive charge generation layer pCGL of the first charge generation layer CGL1 and the red light emitting layer REML, and may further include the electron transport layer ETL between the green light emitting layer GEML and the negative charge generation layer nCGL of the second charge generation layer CGL2.

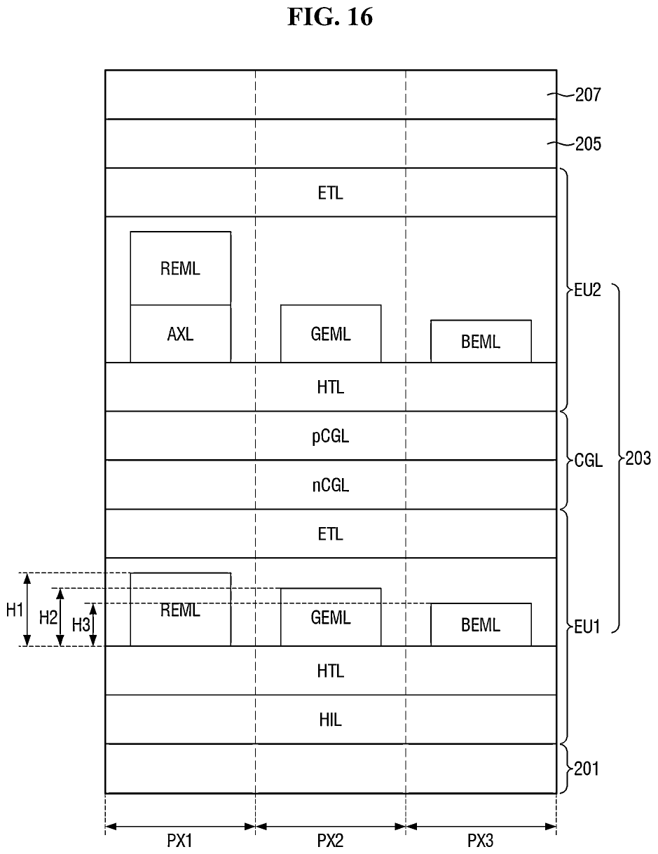

FIG. 16 is a cross-sectional view illustrating a structure of a pixel of a display device according to some embodiments.

Referring to FIG. 16, the display device 1000 may include a plurality of pixels. The plurality of pixels may include the first pixel PX1, the second pixel PX2, and the third pixel PX3. Each of the first pixel PX1, the second pixel PX2, and the third pixel PX3 may include the pixel electrode 201, the common electrode 205, and the intermediate layer 203. According to some embodiments, the first pixel PX1 may be a red pixel, the second pixel PX2 may be a green pixel, and the third pixel PX3 may be a blue pixel.

The pixel electrode 201 may be independently provided in each of the first pixel PX1, the second pixel PX2, and the third pixel PX3.

The intermediate layer 203 of each of the first pixel PX1, the second pixel PX2, and the third pixel PX3 may include the first emitting unit EU1 and the second emitting unit EU2 that are sequentially stacked, and the charge generation layer CGL between the first emitting unit EU1 and the second emitting unit EU2. The charge generation layer CGL may include the negative charge generation layer nCGL and the positive charge generation layer pCGL. The charge generation layer CGL may be a common layer continuously formed in the first pixel PX1, the second pixel PX2, and the third pixel PX3.

The first emitting unit EU1 of the first pixel PX1 may include the hole injection layer HIL, the hole transport layer HTL, the red light emitting layer REML, and the electron transport layer ETL that are sequentially stacked on the pixel electrode 201. The first emitting unit EU1 of the second pixel PX2 may include the hole injection layer HIL, the hole transport layer HTL, the green light emitting layer GEML, and the electron transport layer ETL that are sequentially stacked on the pixel electrode 201. The first emitting unit EU1 of the third pixel PX3 may include the hole injection layer HIL, the hole transport layer HTL, the blue light emitting layer BEML, and the electron transport layer ETL that are sequentially stacked on the pixel electrode 201. Each of the hole injection layer HIL, the hole transport layer HTL, and the electron transport layer ETL of the first emitting unit EU1 may be a common layer continuously formed in the first pixel PX1, the second pixel PX2, and the third pixel PX3.

The second emitting unit EU2 of the first pixel PX1 may include the hole transport layer HTL, an auxiliary layer AXL, the red light emitting layer REML, and the electron transport layer ETL that are sequentially stacked on the charge generation layer CGL. The second emitting unit EU2 of the second pixel PX2 may include the hole transport layer HTL, the green light emitting layer GEML, and the electron transport layer ETL that are sequentially stacked on the charge generation layer CGL. The second emitting unit EU2 of the third pixel PX3 may include the hole transport layer HTL, the blue light emitting layer BEML, and the electron transport layer ETL that are sequentially stacked on the charge generation layer CGL. Each of the hole transport layer HTL and the electron transport layer ETL of the second emitting unit EU2 may be a common layer continuously formed in the first pixel PX1, the second pixel PX2, and the third pixel PX3. According to some embodiments, at least one of a hole blocking layer or a buffer layer may be further included between the light emitting layer and the electron transport layer ETL in the second emitting unit EU2 of the first pixel PX1, the second pixel PX2, and the third pixel PX3.

A thickness H1 of the red light emitting layer REML, a thickness H2 of the green light emitting layer GEML, and a thickness H3 of the blue light emitting layer BEML may be determined according to the resonance distance. The auxiliary layer AXL may be a layer added to adjust the resonance distance, and may include a resonance auxiliary material. For example, the auxiliary layer AXL may include the same material as the hole transport layer HTL.

In FIG. 16, the auxiliary layer AXL may be located only in the first pixel PX1, but the embodiments of the present disclosure are not limited thereto. For example, the auxiliary layer AXL may be located in at least one of the first pixel PX1, the second pixel PX2, or the third pixel PX3 to adjust the resonance distance of each of the first pixel PX1, the second pixel PX2, and the third pixel PX3.

The display device 1000 may further include a capping layer 207 located outside the common electrode 205. The capping layer 207 may serve to relatively improve luminous efficiency by the principle of constructive interference. Accordingly, the light extraction efficiency of a light emitting element (e.g., an organic light emitting diode) may be increased, so that the luminous efficiency of the light emitting element (e.g., the organic light emitting diode) may be relatively improved.

In concluding the detailed description, those skilled in the art will appreciate that many variations and modifications can be made to the disclosed embodiments without substantially departing from the spirit and scope of embodiments according to the present disclosure. Therefore, the disclosed embodiments of the invention are used in a generic and descriptive sense only and not for purposes of limitation.

What is claimed is:

1. A display device comprising:
a substrate;
a first display layer on a first surface of the substrate;
a second display layer on a second surface of the substrate;
a first pixel of the first display layer; and
a second pixel of the second display layer,
wherein the first pixel and the second pixel comprise different numbers of transistors.

2. The display device of claim 1, wherein a second pixel circuit of the second pixel comprises a larger number of transistors than a first pixel circuit of the first pixel.

3. The display device of claim 2, wherein the first pixel circuit comprises five transistors, and
the second pixel circuit comprises eight transistors.

4. The display device of claim 3, wherein the first pixel circuit comprises:
a first transistor comprising a gate electrode connected to a first node, and connected between a second node and a third node;
a second transistor comprising a gate electrode connected to a first gate line, and connected between a data line and the first node;
a third transistor comprising a gate electrode connected to a third gate line, and connected between a reference voltage line and the first node;
a fourth transistor comprising a gate electrode connected to a second gate line, and connected between a third node and an initialization voltage line; and
a fifth transistor comprising a gate electrode connected to an emission line, and connected between a driving voltage line and the second node.

5. The display device of claim 4, wherein the first to fifth transistors each contain an oxide semiconductor material.

6. The display device of claim 4, wherein the first to fifth transistors are n-type transistors.

7. The display device of claim 4, wherein the second transistor further comprises a counter gate electrode connected to the first gate line,
the third transistor further comprises a counter gate electrode connected to the third gate line, and
the fourth transistor further comprises a counter gate electrode connected to the second gate line.

8. The display device of claim 4, wherein the first pixel circuit further comprises:
a first capacitor connected between the first node and the third node; and
a second capacitor connected between the driving voltage line and the third node.

9. The display device of claim 3, wherein the second pixel circuit comprises:
a first transistor comprising a gate electrode connected to a third node, and connected between a first node and a second node;
a second transistor comprising a gate electrode connected to a first gate line, and connected between a data line and the first node;
a third transistor comprising a gate electrode connected to a second gate line, and connected between the third node and the second node;
a fourth transistor comprising a gate electrode connected to a third gate line, and connected between the third node and a first initialization voltage line;
a fifth transistor comprising a gate electrode connected to an emission line, and connected between a driving voltage line and the first node;
a sixth transistor comprising a gate electrode connected to the emission line, and connected between the second node and a fourth node;
a seventh transistor comprising a gate electrode connected to a fourth gate line, and connected between the fourth node and a second initialization voltage line; and
an eighth transistor comprising a gate electrode connected to the fourth gate line, and connected between a bias voltage line and the first node.

10. The display device of claim 9, wherein the first transistor, the second transistor, the fifth transistor, the sixth transistor, the seventh transistor, and the eighth transistor each contain a silicon-based semiconductor material, and
the third transistor and the fourth transistor each contain an oxide semiconductor material.

11. The display device of claim 9, wherein the first transistor, the second transistor, the fifth transistor, the sixth transistor, the seventh transistor, and the eighth transistor are p-type transistors, and
the third transistor and the fourth transistor are p-type transistors.

12. The display device of claim 9, wherein the third transistor further comprises a counter gate electrode connected to the second gate line, and
the fourth transistor further comprises a counter gate electrode connected to the third gate line.

13. The display device of claim 9, wherein the second pixel circuit further comprises a capacitor connected between the driving voltage line and the third node.

14. The display device of claim 1, wherein the first display layer and the second display layer have different areas.

15. The display device of claim 14, wherein the first display layer has a larger area than that of the second display layer.

16. The display device of claim 15, further comprising a driving circuit on the second surface and connected to the first display layer and the second display layer.

17. The display device of claim 16, wherein the driving circuit is connected to the first display layer through a first pad terminal of the driving circuit, and
the driving circuit is connected to the second display layer through a second pad terminal of the driving circuit.

18. The display device of claim 17, wherein the first pad terminal is connected to the first display layer through a first pad on the second surface, and
the second pad terminal is connected to the second display layer through a second pad on the second surface.

19. The display device of claim 17, wherein the driving circuit supplies a gate signal, a data signal, and an emission signal to the first display layer through the first pad terminal, and
the driving circuit supplies a gate signal, a data signal, and an emission signal to the second display layer through the second pad terminal.

20. The display device of claim 2, wherein the first pixel further comprises a first light emitting element connected to the first pixel circuit, and
the second pixel further comprises a second light emitting element connected to the second pixel circuit.
